(19) United States
(12) Patent Application Publication
(10) Pub. No.: US 2008/0121987 A1
(43) Pub. Date: May 29, 2008

(54) Nanodot and nanowire based MOSFET structures and fabrication processes

(76) Inventor: Yijian Chen, Albany, CA (US)

Correspondence Address: Yijian Chen, 1049 Talbot Avenue, Albany, CA, 94706, US

(21) Appl. No.: 11/592,846

(22) Filed: Nov. 6, 2006

(51) Int. Cl. H01L 29/78; H01L 21/04

(52) U.S. Cl. 257/328; 438/268; 977/938; 257/E29.262; 257/E21.04

(57) ABSTRACT

Novel nanodot and nanowire based MOSFET device structures and their fabrication processes are invented. These devices can be fabricated with the processes that do not need the extremely high lithographic resolution. The MOSFET devices remain functional even the nanodots and nanowires with varying sizes are randomly distributed. The activated number of nanodots and its total effective channel length/width are affected by the polished thickness of the insulation material in the CMP process. Therefore it is important to have a highly accurate control of CMP polishing rate to ensure a reliable process.

Nanodot and nanowire based MOSFETs for device scaling down to (half-pitch) sub-10 nm generation have attracted extensive research interest recently owing to its efficient large-scale bottom-up fabrication process [1-5], yet a critical challenge is the necessary uniformity control of the size and location of nanodots and nanowires fabricated in a production-worthy manner. A cost-effective lithography technology to pattern sub-10 nm features for high-volume semiconductor manufacturing will be extremely difficult, if not impossible. Therefore, it is important to research a MOSFET device architecture that can tolerate the statistical fluctuation of nanodot and nanowire size and location, and develop a fabrication process that does not need the extremely high resolution capability with a conventional lithographic tool.

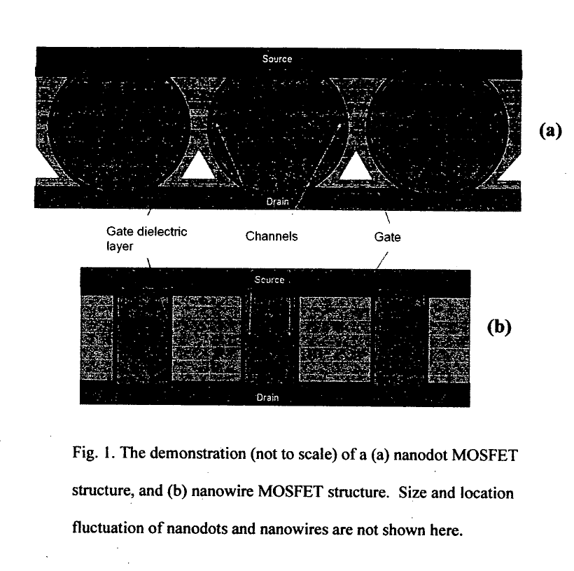

FIG. 1 is a conceptual demonstration of nanodot and nanowire n-MOSFETs (also applicable for p-MOSFETs if dopings n and p are exchanged). We demonstrate the process flow with Si body as an example, but any relevant semiconductor material (e.g., Ge, SiGe, to name a few) can be used for the body/channel. The n+ doped source/drain regions are arranged in the vertical direction to save space. Even uniform individual device structures are shown in this figure, their fabrication processes (to be shown later) are able to produce functional devices regardless of the statistical fluctuation of nanodot/nanowire size and location.

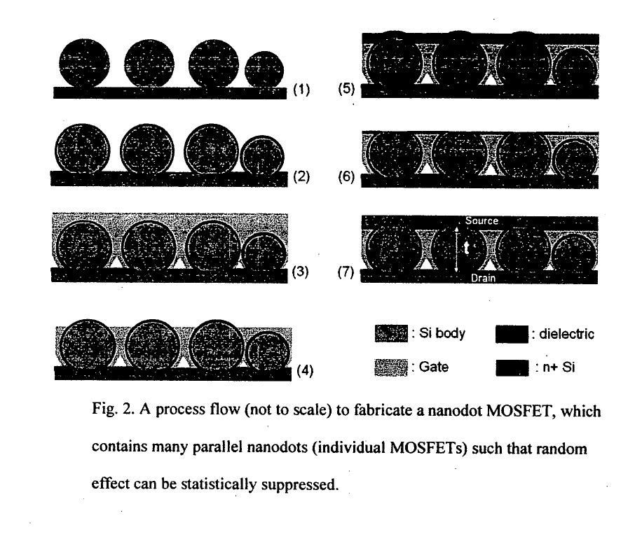

FIG. 2 shows a process flow to fabricate a nanodot MOSFET in which the effect of random distribution of nanodot size and location is averaged out by embedding many dots in one MOSFET. First, we grow a cluster of Si nano-crystals on top of n+ doped drain region followed by a thermal oxidation to grow silicon dioxide as the gate dielectric material. High-K dielectric layer can also be used here. Then the gate material (e.g., heavily doped poly or metal) is put down and CMP process is used to planarize the surface as shown in FIG. 2(3). The gate layer will then be etched down (with highly selective wet etchant or dry etching which does not attack the nanodot structure) such that its surface is slightly below the level of gate oxide. Then an oxide insulation layer is deposited as shown in step (5). A following CMP process in step (6) will polish off some thickness of oxide/dielectric layers such that the Si bodies in the nanodots are exposed while leaving an oxide layer on top of the gate material to act as the insulation layer. This step is important as the insulation layer (after CMP) to separate the gate material from the top n+ doped source region as demonstrated in step (7) is critical to get functional devices. Finally, an n+ doped source layer is deposited followed by a conventional lithographic step defining the active area of MOSFET. Apparently, there is no need to resolve every individual nanodot; and the MOSFET devices remain functional regardless of some nanodots not activated (as shown on the right side in FIG. 2) due to the statistical fluctuation of their radii in the manufacturing process. It is critical that the polished oxide thickness in step (6) is thick enough to expose the Si nano-crystal body, but not too much such that there is still some oxide left on top of the gate material to act as the insulation layer. Moreover, the polished thickness in CMP process will determine whether a nanodot is activated or not (by opening the top oxide layer) as shown in FIG. 2. Therefore, the variation of activated number of nanodots (or the total channel width of MOSFET) is directly related with the CMP polish rate control.

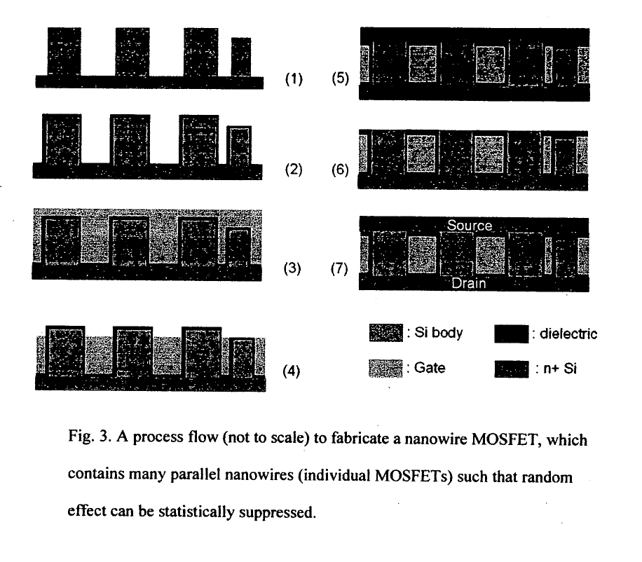

What is shown in FIG. 3 is a similar process flow to fabricate a nanowire based n-MOSFET. The main difference between this process and the nanodot-based process is step (1) wherein a cluster of nanowires is grown on top of the n+ doped substrate.

### REFERENCES

[1] N. Singh, A. Agarwal, L. K. Bera, T. K. Liow, R. Yang, S. C. Rustagi, C. H. Tung, R. Kumar, G. Q. Lo, N. Balasubramanian, and D.-L. Kwong, “High-performance fully depleted silicon nanowire (diameter≦5 nm) gate-all-around CMOS devices,” IEEE Electron Device Letters, Vol. 27, No. 5, pp. 383-386, May 2006.
[2] Y. Cui, Z. Zhong, D. Wang, W. U. Wang, and C. M. Lieber “High performance silicon nanowire field effect transistors,” Nano Letters, Vol. 3, No. 2, pp. 149-152, 2003.
[3] Y. Chen and A. Chu, “Vertical integrated-gate CMOS for ultra-dense IC,” Microelectronic Engineering, Vol. 83, Issues 4-9, pp. 1745-1748, April-September, 2006.
[4] Y. Chen, “Double surrounding-gate control of Si body in vertical Integrated-gate CMOS,” The International Conference on Micro- and Nano-engineering, Barcelona, Spain, Sep. 17-20, 2006.
[5] Y. Chen and J. Luo, “A comparative study of double-gate and surrounding-gate MOSFETs in strong inversion and accumulation using an analytical model,” Technical Proceedings of the Fourth International Conference on Modeling and Simulation of Microsystems, pp. 546-549, 2001.

1. FIG. 1 is a conceptual demonstration of nanodot and nanowire n-MOSFETs. The n+ doped source/drain regions are arranged in the vertical direction to save space. Even uniform individual device structures are shown in this figure, their fabrication processes (to be shown later) are able to produce functional devices regardless of the statistical fluctuation of nanodot/nanowire size and location.

2. Si body is used in FIG. 1 as an example, but any relevant semiconductor material (e.g., Ge, SiGe, to name a few) can be used for the body/channel of nanodot and nanowire based MOSFET devices.

3. Device structures shown in FIG. 1 are also applicable for p-MOSFETs if dopings n and p are exchanged.

4. FIG. 2 shows a process flow to fabricate a nanodot MOSFET in which the effect of random distribution of nanodot size and location is averaged out by embedding many dots in one MOSFET, the process comprising:
a. First, we grow a cluster of Si nano-crystals on top of n+ doped drain region followed by a thermal oxidation to grow silicon dioxide as the gate dielectric material.
b. High-K dielectric material can also be used to replace the thermal oxide as the gate dielectric material.
c. Then the gate material (e.g., heavily doped poly or metal) is put down and CMP process is used to planarize the surface as shown in FIG. 2(3).
d. The gate layer will then be etched down (with highly selective wet etchant or dry etching which does not attack the nanodot structure) such that its surface is slightly below the level of gate oxide.
e. Then an oxide insulation layer is deposited as shown in step (5).
f. A following CMP process in step (6) will polish off some thickness of oxide/dielectric layers such that the Si bodies in the nanodots are exposed while leaving an oxide layer on top of the gate material to act as the insulation layer. This step is important as the insulation layer (after CMP) to separate the gate material from the top n+ doped source region as demonstrated in step (7) is critical to get functional devices.
g. Finally, an n+ doped source layer is deposited followed by a conventional lithographic step defining the active area of MOSFET.
Apparently, there is no need to resolve every individual nanodot; and the MOSFET devices remain functional regardless of some nanodots not activated (as shown on the right side in FIG. 2) due to the statistical fluctuation of their radii in the manufacturing process. It is critical that the polished oxide thickness in step (6) is thick enough to expose the Si nano-crystal body, but not too much such that there is still some oxide left on top of the gate material to act as the insulation layer. Moreover, the polished thickness in CMP process will determine whether a nanodot is activated or not (by opening the top oxide layer) as shown in FIG. 2. Therefore, the variation of activated number of nanodots (or the total channel width of MOSFET) is directly related with the CMP polish rate control.

5. A nanowire based process similar to the process of claim 4. The main difference between this claim 5 and claim 4 is step (1) wherein a cluster of nanowires is grown on top of the n+ doped substrate.
